(19) United States
(12) Patent Application Publication
(10) Pub. No.: US 2026/0144058 A1
(43) Pub. Date: May 21, 2026

(54) SEMICONDUCTOR PACKAGE WITH HEAT DISSIPATION ENHANCED STRUCTURE AND METHOD OF FORMING THE SAME

(71) Applicant: Taiwan Semiconductor Manufacturing Company, Ltd., Hsinchu (TW)

(72) Inventors: Pei-Hsuan LEE, Tainan City (TW); Chao-Wei LI, Hsinchu City (TW); Cheng-Chi HSIEH, Hsinchu City (TW); Yu-Hsiang HU, Hsinchu City (TW); Chien-Hsun LEE, Hsin-chu County (TW)

(73) Assignee: Taiwan Semiconductor Manufacturing Company, Ltd., Hsinchu (TW)

(21) Appl. No.: 18/955,210

(22) Filed: Nov. 21, 2024

(51) Int. Cl. H01L 23/367; H01L 23/373; H01L 23/498; H01L 23/538; H01L 25/065

(52) U.S. Cl. CPC H10W 40/22; H10W 40/255; H10W 70/611; H10W 90/401; H10W 90/701; H10W 90/00

(57) ABSTRACT

A chip package structure is provided. The chip package structure includes a package substrate and a semiconductor device mounted on the package substrate. A heat dissipation layer includes a first portion covering the top surface of the semiconductor device, a second portion covering the sidewall of the semiconductor device, and a third portion covering the top surface of the package substrate. The first portion, second portion and third portion are connected to each other. At least one thermal via is formed through the package substrate to contact the third portion of the heat dissipation layer.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

In addition to smaller electronic components, improvements to the packaging of components have been developed in an effort to provide smaller packages that take up less space than previous packages. Examples of these approaches include quad flat pack (QFP), pin grid array (PGA), ball grid array (BGA), flip chips (FC), three-dimensional integrated circuits (3DICs), wafer level packages (WLPs), package on package (PoP), System-on-Chip (SoC), and System-on-Integrated-Circuit (SoIC) devices. Some of these three-dimensional devices (e.g., 3DIC, SoC, SoIC devices) are prepared by placing chips (or dies) over chips (or dies) on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1H are cross-sectional views of various stages in the formation of a chip package structure, in accordance with some embodiments.

FIG. 1B-1 is a top view of the chip package structure shown in FIG. 1B, in accordance with some embodiments.

FIG. 1C-1 is a top view of the chip package structure shown in FIG. 1C, in accordance with some embodiments.

FIG. 1F-1 is a top view of the chip package structure shown in FIG. 1F, in accordance with some embodiments.

FIGS. 1F-2, 1F-3, and 1F-4 are top views showing different arrangements of thermal vias in a package substrate, in accordance with some embodiments.

FIG. 1G-1 is a top view of the chip package structure shown in FIG. 1G, in accordance with some embodiments.

FIGS. 1G-2, 1G-3, and 1G-4 are top views showing different arrangements of a heat dissipation layer within the chip package structure, in accordance with some embodiments.

FIG. 2 is a cross-sectional view of an integrated circuit device, in accordance with some embodiments.

FIG. 3 is a cross-sectional view of a chip package structure, in accordance with some embodiments.

FIG. 4 is a cross-sectional view of a chip package structure, in accordance with some embodiments.

FIG. 5 is a cross-sectional view of a chip package structure, in accordance with some embodiments.

FIG. 6 is a cross-sectional view of a chip package structure, in accordance with some embodiments.

FIG. 7 is a cross-sectional view of a chip package structure, in accordance with some embodiments.

FIG. 8 is a cross-sectional view of a chip package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide three-dimensional integrated circuit (3DIC) packages (e.g., Chip-on-Wafer-on-Substrate (CoWoS) packages) with heat dissipation enhanced structures for better thermal performance (e.g., heat dissipation) in High Performance Computing (HPC) applications which require extremely high power and high power density at die regions. The heat dissipation enhanced structure includes a heat dissipation layer formed to extend from the top surface of the Chip-on-Wafer (CoW) device (or die) disposed on the package substrate along the sidewalls of the CoW device to the top surface of the package substrate. By forming this heat dissipation layer as an additional heat transfer path, the heat generated by the integrated circuit (IC) dies within the CoW device can be transferred laterally and downwardly to the package substrate along this heat transfer path (rather than just being dissipated upward through upper heat dissipation mechanisms, such as a thermal lid and/or a heat sink above the CoW device). Therefore, heat accumulation between the CoW device and the upper heat dissipation mechanisms can be reduced or avoided, thereby improving the heat dissipation efficiency of the entire package structure. In accordance with some embodiments, the heat dissipation layer can also serve as an electromagnetic interference shielding layer to prevent the CoW device from being interfered by external signals. In this way, the performance reliability of the package structure may be improved. Details of the heat dissipation enhanced structure and some variations of some embodiments are described below.

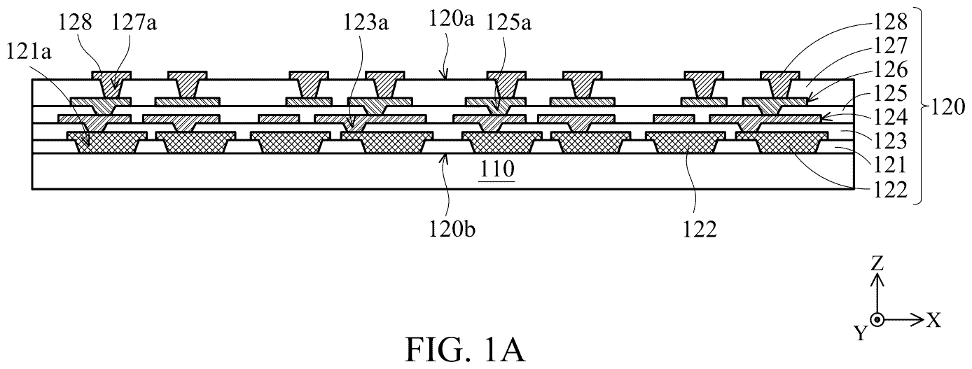

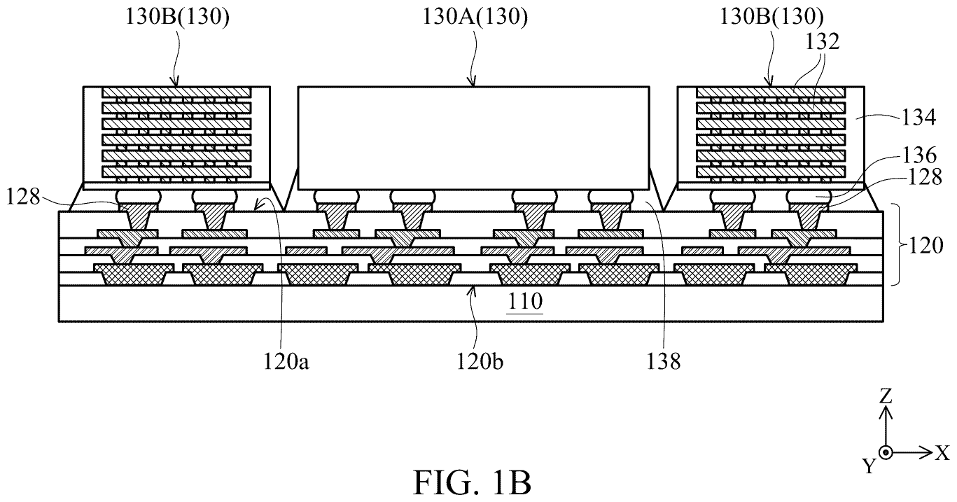

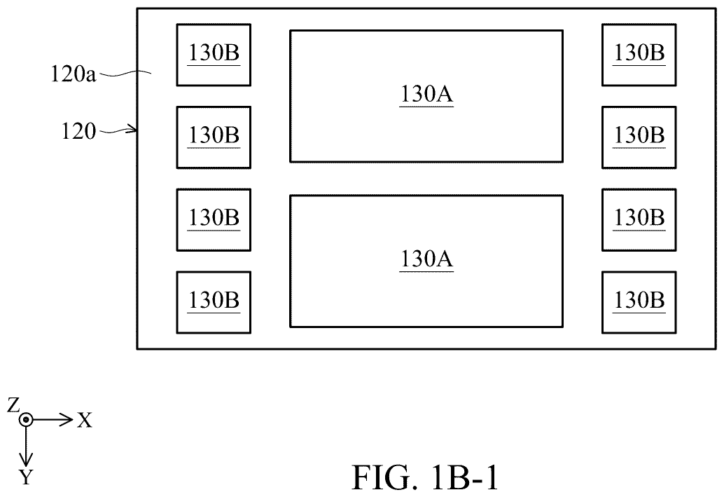

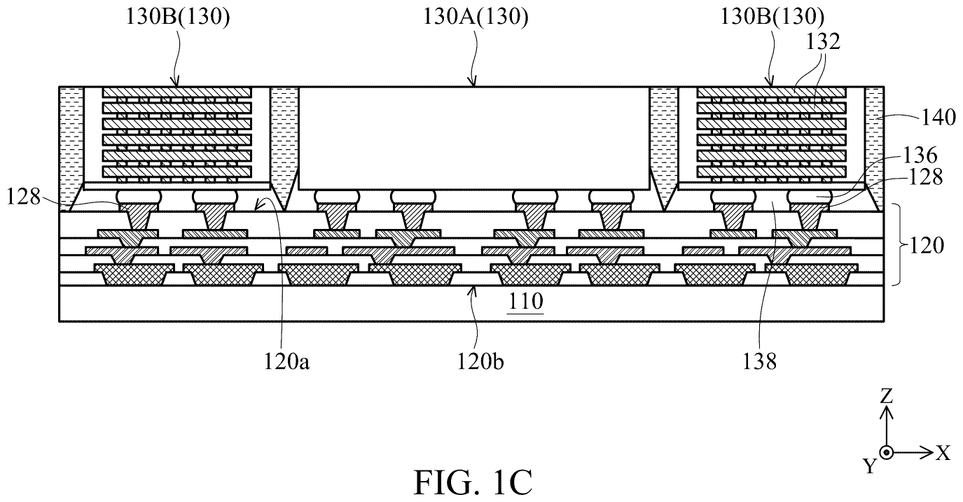

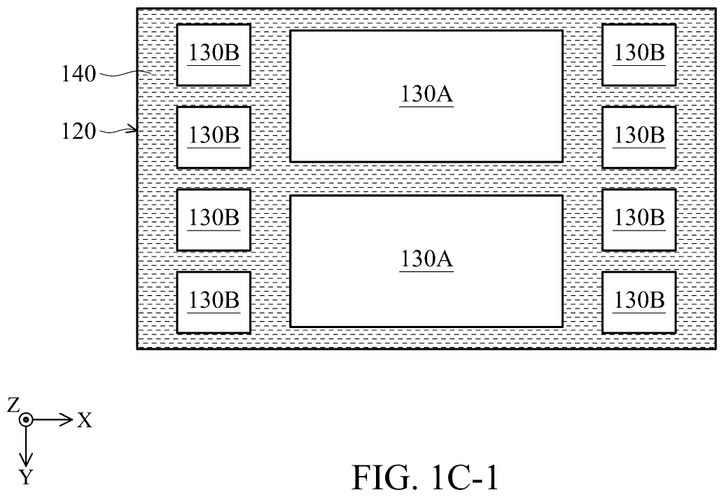

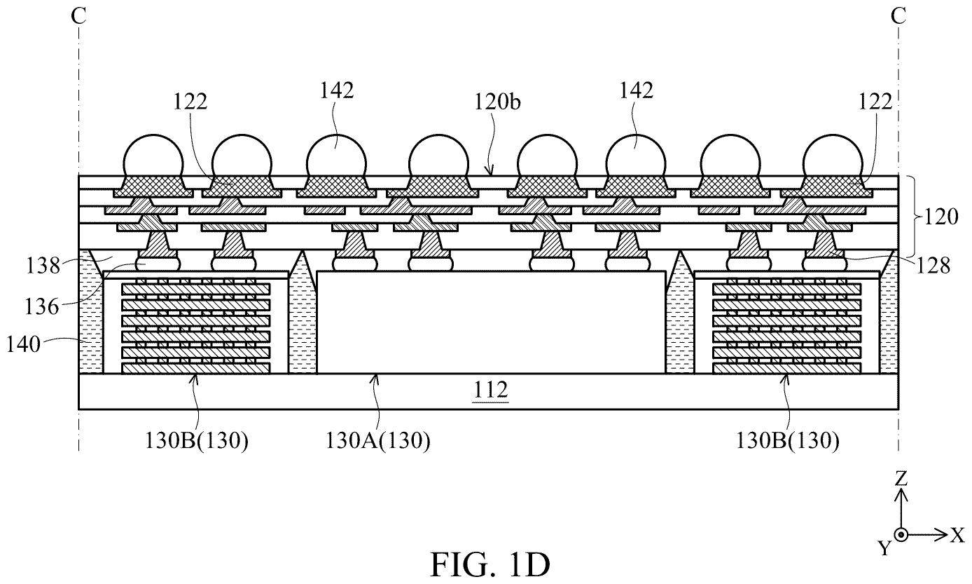

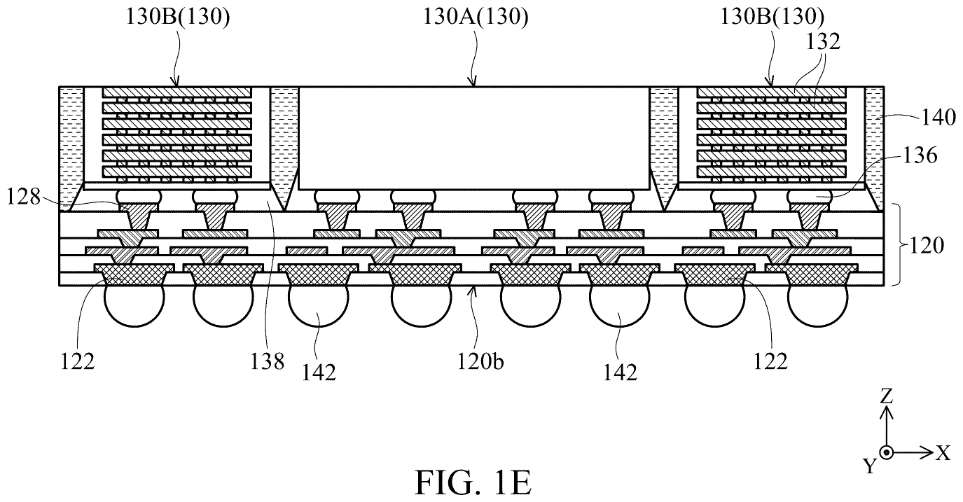

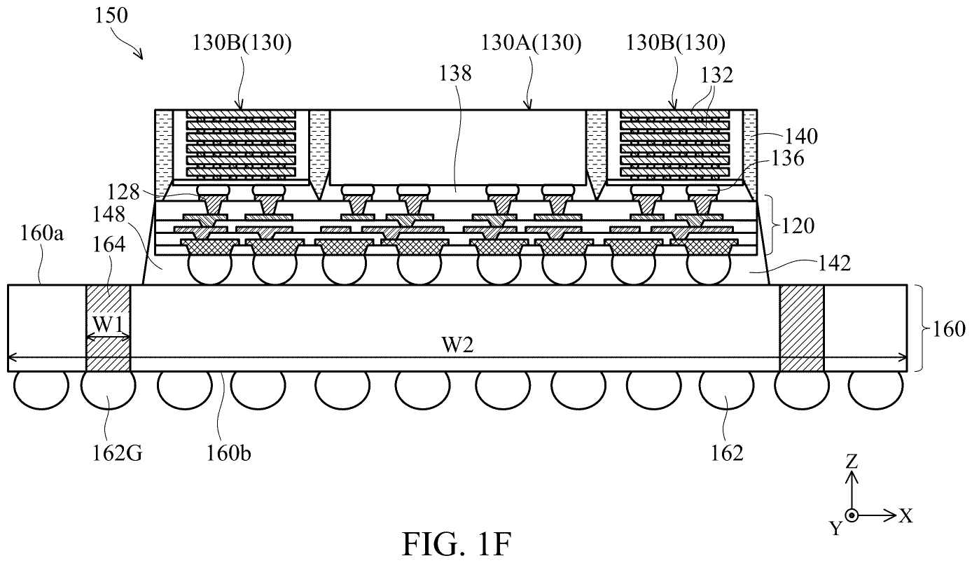

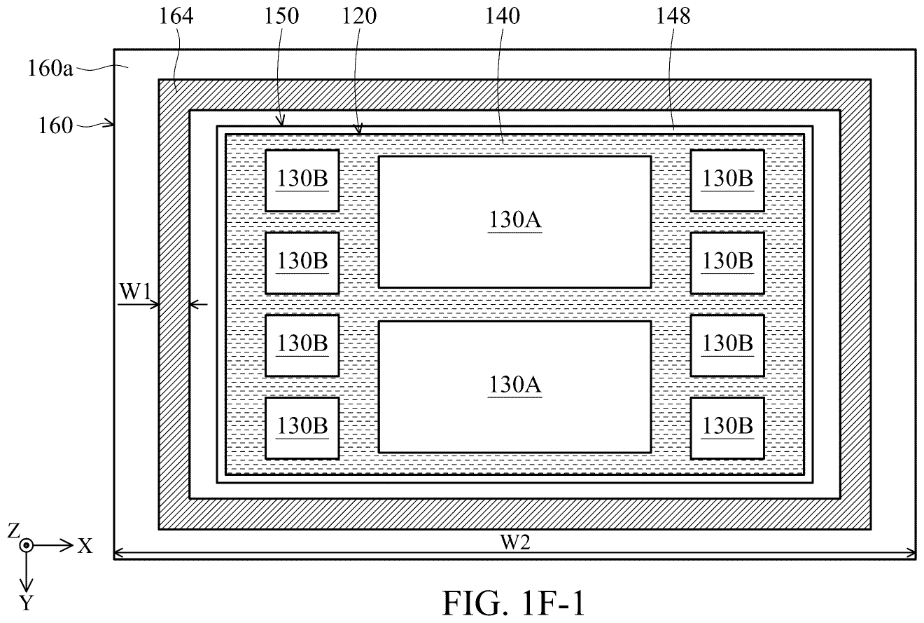

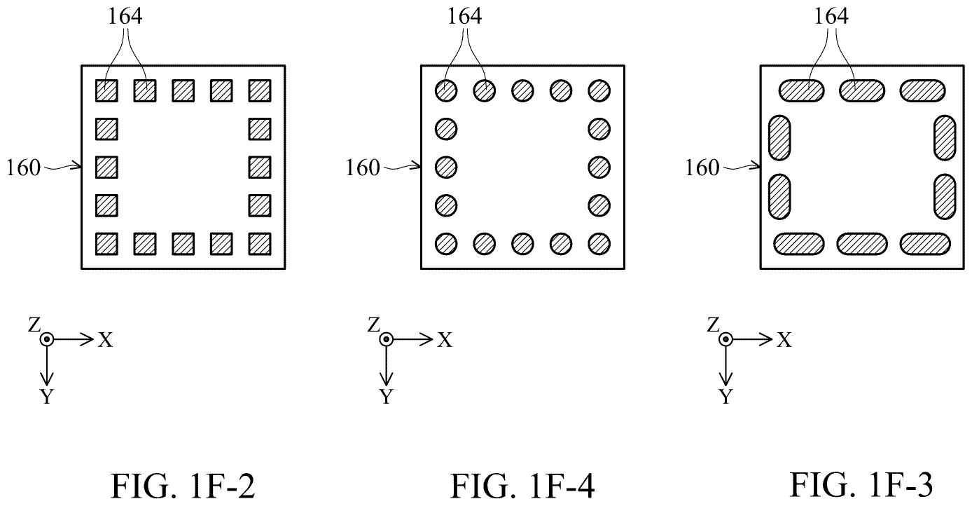

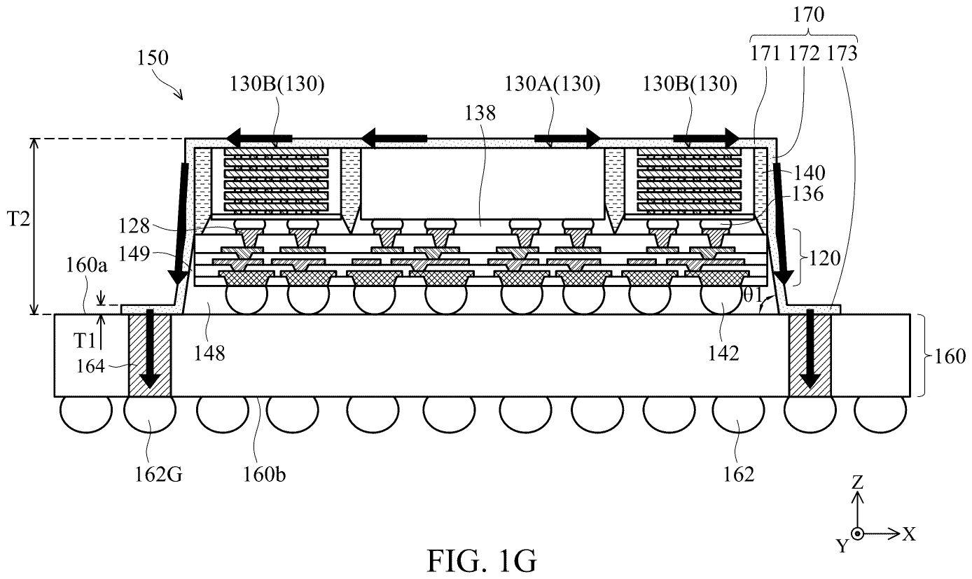

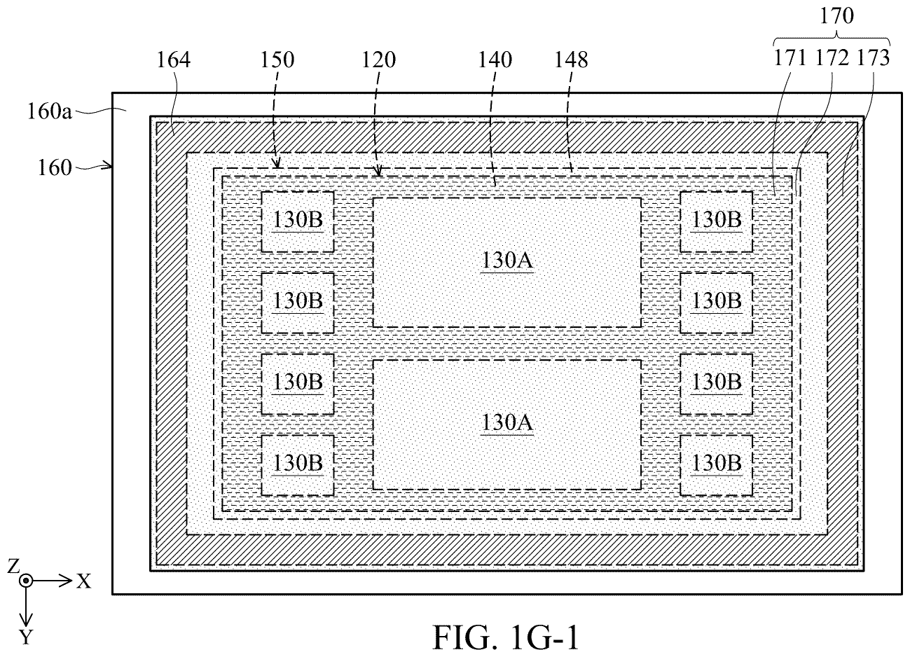

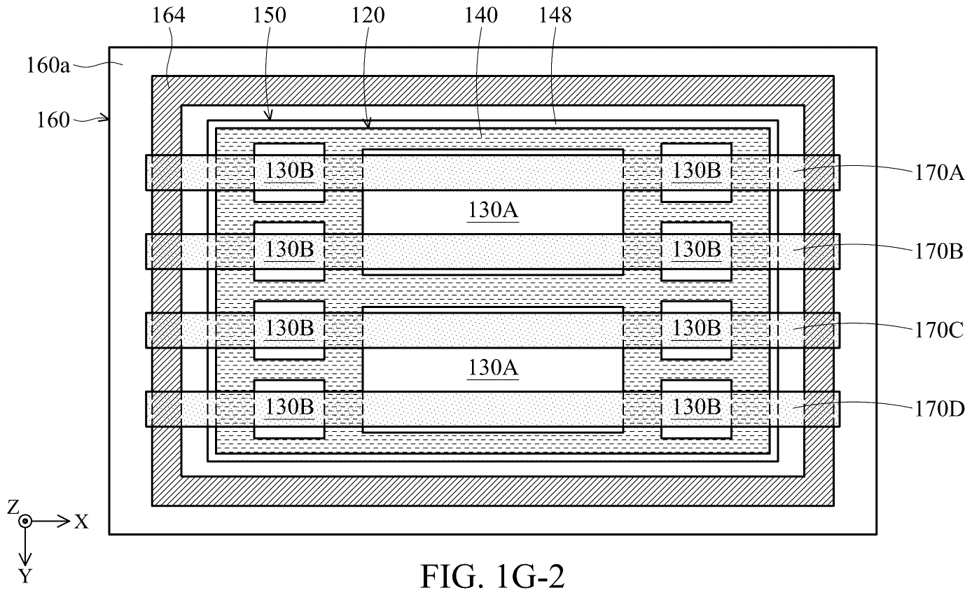

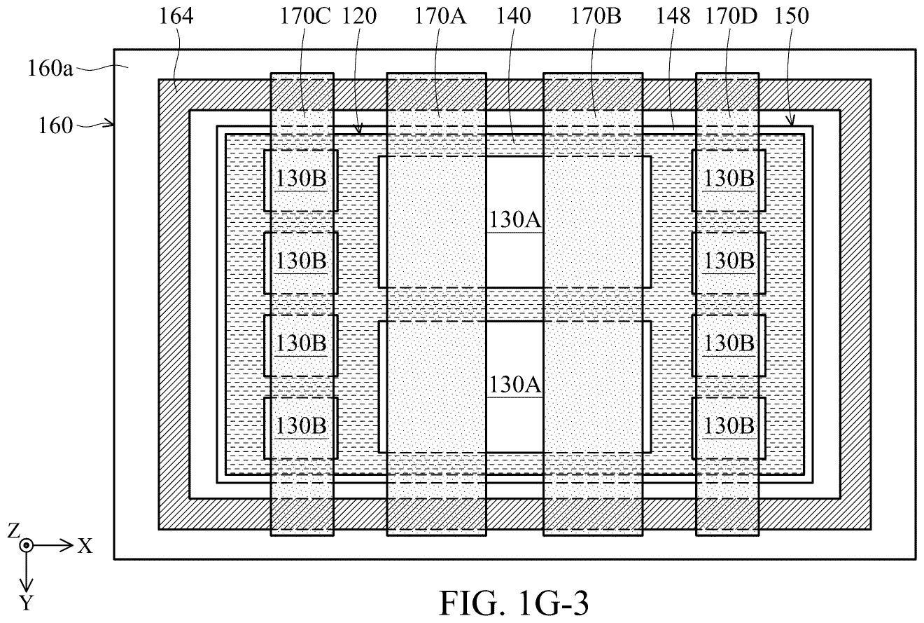

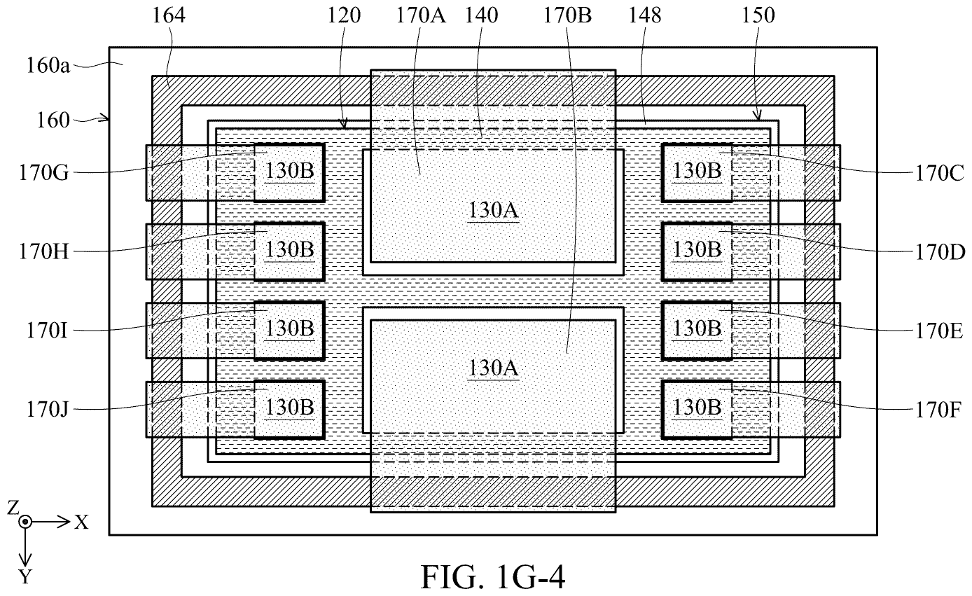

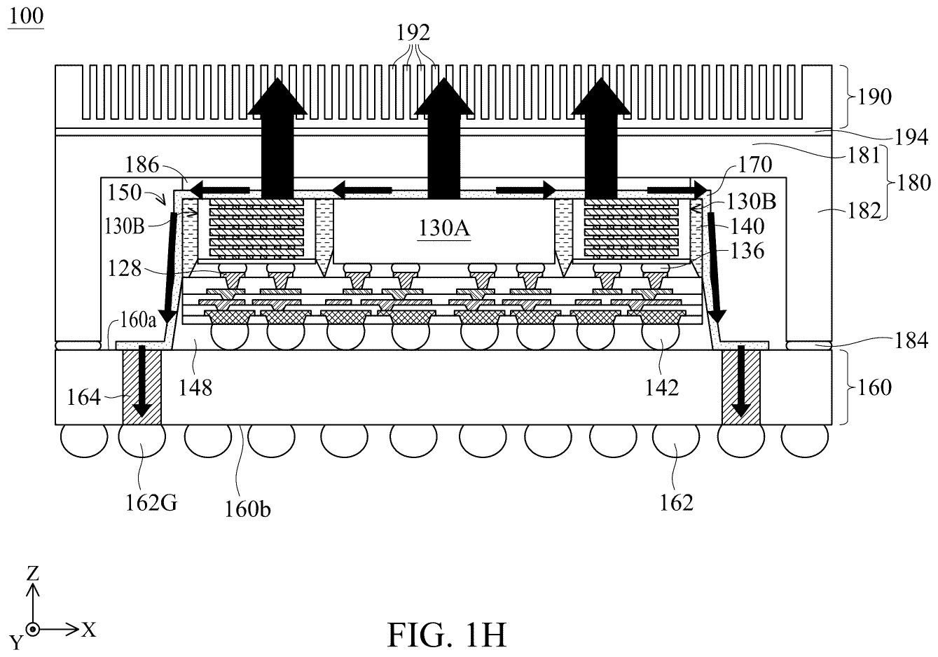

FIGS. 1A to 1H are cross-sectional views of various stages in the formation of a chip package structure 100 (e.g., CoWoS package, see FIG. 1H), in accordance with some embodiments. As shown in FIG. 1A, a carrier substrate 110 is provided, in accordance with some embodiments. The carrier substrate 110 is configured to provide temporary mechanical and structural support during subsequent processing steps. The material of the carrier substrate 110 includes glass, silicon, silicon oxide, aluminum oxide, metal, a combination thereof, or the like, in accordance with some embodiments. The carrier substrate 110 includes a metal frame, in accordance with some embodiments.

A distribution structure 120 is then formed over the carrier substrate 110, in accordance with some embodiments. The redistribution structure 120 is in wafer form (i.e., includes multiple identical die regions) and has two opposite surfaces 120a and 120b, in accordance with some embodiments. For simplicity, only one die region is shown. The formation of the redistribution structure 120 includes forming an insulating layer 121 over the carrier substrate 110; forming conductive pads 122 over the insulating layer 121 and in through holes 121a of the insulating layer 121; forming an insulating layer 123 over the insulating layer 121 and the conductive pads 122; forming a wiring layer 124 over the insulating layer 123 and in through holes 123a of the insulating layer 123; forming an insulating layer 125 over the insulating layer 123 and the wiring layer 124; forming a wiring layer 126 over the insulating layer 125 and in through holes 125a of the insulating layer 125; forming an insulating layer 127 over the insulating layer 125 and the wiring layer 126; and forming conductive pads 128 over the insulating layer 127 and in through holes 127a of the insulating layer 127.

The wiring layers 124 and 126 are electrically connected to each other, in accordance with some embodiments. The conductive pads 122 and 128 are electrically connected to the wiring layers 124 and 126, in accordance with some embodiments. The insulating layers 121, 123, 125, and 127 are made of an insulating material such as a polymer material (e.g., polybenzoxazole, polyimide, or a photosensitive material), nitride (e.g., silicon nitride), oxide (e.g., silicon oxide), silicon oxynitride, or the like, in accordance with some embodiments. The wiring layers 124 and 126 and the conductive pads 122 and 128 are made of a conductive material, such as metal (e.g. copper, aluminum, or tungsten), in accordance with some embodiments.

As shown in FIG. 1B, package components 130A and 130B are bonded to the underlying distribution structure 120, in accordance with some embodiments. FIG. 1B-1 is a top view of the chip package structure shown in FIG. 1B, in accordance with some embodiments. In FIG. 1B-1, two package components 130A and eight package components 130B are illustrated and are bonded to the same distribution structure 120 (e.g., the two package components 130A are arranged side by side in the central area of the top surface 120a of the distribution structure 120, and the eight package components 130B are respectively arranged around the two package components 130A and adjacent to two opposite sides of the top surface 120a); however, any number of the package components 130A or 130B can be bonded to the distribution structure 120, and can be in any arrangement. In some embodiments, the package components 130A and 130B are different types of package components, and are collectively referred to as package components 130 (see FIG. 1B).

In some embodiments, each of the package components 130 includes a device die, a package including a device die packaged therein, a System-on-Chip (SoC) or System-on-Integrated-Circuit (SoIC) device/die including a plurality of integrated circuits (or device dies) integrated as a system, or the like. The device dies in the package components 130 may be or may include logic dies, memory dies, input-output dies, Integrated Passive Devices (IPDs), a combination thereof, or the like. For example, the logic device dies in the package components 130 are Central Processing Unit (CPU) dies, Graphic Processing Unit (GPU) dies, mobile application dies, Micro Control Unit (MCU) dies, BaseBand (BB) dies, Application processor (AP) dies, or the like. In some embodiments, the memory dies in the package components 130 include Static Random Access Memory (SRAM) dies, Dynamic Random Access Memory (DRAM) dies, or the like. In some embodiments, the device dies in the package components 130 include semiconductor substrates and interconnect structures.

In the illustrated embodiment, the package components 130A are referred to as device dies, which may be SoC or SoIC dies (for simplicity, the internal structures are not shown), and the package components 130B are memory stacks, such as High Bandwidth Memory (HBM). As shown in FIG. 1B, the package components 130B each include memory dies 132 forming a die stack, and an encapsulant 134 (such as a molding compound) encapsulating the memory dies 132 therein. When viewed from the top, the encapsulant 134 may form a ring encircling the memory dies 132, and may also extend into the gaps between the memory dies 132 to contact conductive connectors (e.g., micro bumps, not specifically labeled) therebetween. In some embodiments, the package components 130A and 130B may have the same or different heights (e.g., in the Z-direction). In some embodiments, the package components 130A and 130B may have the same or different surface areas (e.g., in the X-Y plane).

The package components 130A and 130B are bonded to the distribution structure 120 through conductive bumps 136, in accordance with some embodiments. The conductive bumps 136 are formed between conductive pads (not shown) exposed at the active surfaces (e.g., the lower surface shown) of the package components 130A and 130B and the conductive pads 128 exposed at the top surface 120a of the distribution structure 120 to electrically connect the package components 130A and 130B to the distribution structure 120. The conductive bumps 136 are made of or include a solder material, such as Sn and Ag or another suitable conductive material (e.g., gold), in accordance with some embodiments. The conductive bumps 136 are solder balls, in accordance with some embodiments.

As shown in FIG. 1B, an underfill layer 138 is formed between the gaps between each of the package components 130 and the distribution structure 120 to surround and protect the conductive bumps 136 and the conductive pads 128, in accordance with some embodiments. The material of the underfill layer 138 may include an epoxy, a resin, a filler material, a stress release agent (SRA), an adhesion promoter, another suitable material, or a combination thereof. In some embodiments, the material of the underfill layer 138 is dispensed in a liquid state and then cured. In other embodiments, the underfill layer 138 is omitted.

As shown in FIG. 1C, an encapsulant 140 is formed over the package components 130, the underfill layer 138 (if present), and the distribution structure 120, in accordance with some embodiments. The encapsulant 140 fills the gaps between neighboring package components 130, and further covers the package components 130, in accordance with some embodiments. The encapsulant 140 may include a molding compound, a molding underfill, or the like. The encapsulant 140 may include a polymer material, such as an epoxy-based resin with fillers dispersed therein. In some embodiments, the encapsulant 140 is dispensed in a liquid state and then cured.

In some embodiments, a planarization process (e.g., a chemical mechanical polishing (CMP) process or a mechanical grinding process) may be performed on the encapsulant 140 to partially remove the encapsulant material, until the top surfaces of the package components 130 are exposed from the encapsulant 140. FIG. 1C-1 is a top view of the chip package structure shown in FIG. 1C, in accordance with some embodiments, in which the top surfaces of the package components 130 (including 130A and 130B) are shown exposed after the planarization process. In some embodiments, the planarization process may be omitted, for example, if the top surfaces of the package components 130 are already exposed.

As shown in FIG. 1D, a tape layer 112 (e.g., dicing tape) is attached to the top surfaces of the package components 130A and 130B and the encapsulant 140, in accordance with some embodiments. The tape layer 112 may be made of a polymer material or another suitable material. The distribution structure 120 is then flipped upside down, and the carrier substrate 110 is removed to expose the surface 120b of the distribution structure 120, in accordance with some embodiments.

Still referring to FIG. 1D, conductive connectors 142 are respectively formed on the conductive pads 122 exposed at the surface 120b, in accordance with some embodiments. The conductive connectors 142 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 142 may include a conductive material such as solder, copper, aluminum, gold, nickel, silver, palladium, tin, the like, or a combination thereof. In some embodiments, the conductive connectors 142 are formed by initially forming a layer of solder through evaporation, electroplating, printing, solder transfer, ball placement, or the like. Once a layer of solder has been formed on the structure, a reflow may be performed in order to shape the material into the desired bump shapes.

Afterwards, a singulation process (e.g., a saw process) is performed along cutting grooves C shown in FIG. 1D, to form multiple separate, identical package structures, in accordance with some embodiments. In FIG. 1D, only one of the package structures is shown. Afterwards, each package structure may be removed from the tape layer 112 using, for example, a pick-and-place tool (not shown).

FIG. 1E is a cross-sectional view of the resulting package structure in FIG. 1D, the only difference is that the package structure is flipped upside down. As shown in FIG. 1E, the resulting package structure 150 includes a distribution structure 120, package components 130A and 130B over the distribution structure 120, an underfill layer 138, an encapsulant 140, and conductive connectors 142. The distribution structure 120 may be used to electrically interconnect the package components 130A and 130B thereon, and may be used to electrically interconnect these package components to an underlying package substrate in a subsequent processing step (e.g., see FIG. 1F). The distribution structure 120 is referred to as a redistribution line (RDL) interposer 120, in accordance with some embodiments. In other illustrated embodiments, the RDL interposer 120 may be replaced by a silicon interposer. Details of a silicon interposer are not described here. The package structure 150 is referred to as a Chip-on-Wafer (CoW) device 150, in accordance with some embodiments.

As shown in FIG. 1F, the CoW device 150 is bonded to a package substrate 160 through the conductive connectors 142, in accordance with some embodiments. For example, the conductive connectors 142 (e.g., solder balls) are reflowed after the placement of the CoW device 150 onto the package substrate 160, to physically and electrically connect the CoW device 150 to the package substrate 160. An underfill layer 148 is then formed between the gap between CoW device 150 and the package substrate 160 to surround and protect the conductive connectors 142, in accordance with some embodiments. The material and formation method of the underfill layer 148 may be similar to those of the underfill layer 138 described above. In some embodiments, the underfill layer 148 includes a fillet portion 149 formed (e.g., accumulated) outside the periphery (e.g., lower edges) the CoW device 150 and extending to the sidewalls of the CoW device 150, as shown in FIG. 1F. In other embodiments, the fillet portion 149 may not exist. In some embodiments, other bonding schemes such as metal-to-metal direct bonding, hybrid bonding, or the like, may be used for bonding the CoW device 150 to the package substrate 160.

In some embodiments, the package substrate 160 is used to provide an electrical connection between the devices or dies packaged in the package structure (e.g., the CoW device 150) and an external electronic device. Although not shown, the package substrate 160 includes electrically conductive features (e.g., conductive lines and vias) to interconnect the contact pads that are exposed at opposite outermost surfaces 160a and 160b of the package substrate 160. The package substrate 160 may be a cored or coreless substrate. In some embodiments, the package substrate 160 may be a printed circuit board (PCB), a ceramic substrate, or another suitable package substrate. In some embodiments, multiple conductive connectors 162 are formed on the bottom surface 160b of the package substrate 160 to provide an external electrical connection. The conductive connectors 162 may be BGA connectors, solder balls, metal pillars, C4 bumps, micro bumps, electroless nickel-electroless palladium-immersion gold technique (ENEPIG) formed bumps, or the like. The material and formation method of the conductive connectors 162 may be similar to those of the conductive connectors 142 described above.

Still referring to FIG. 1F, one or more thermal vias 164 are pre-formed in (e.g., penetrating through) the package substrate 160, in accordance with some embodiments. The thermal vias 164 may be arranged around the CoW device 150 in plan view (e.g., see FIG. 1F-1), in accordance with some embodiments. The location of the thermal vias 164 may correspond to (e.g., vertically overlap) the location of a heat dissipation layer 170 that will be formed on the package substrate 160 in a subsequent processing step (e.g., see FIG. 1G) and the location of one or more conductive connectors 162 underneath the package substrate 160 physically and thermally coupled to the thermal vias 164, in accordance with some embodiments. Accordingly, the thermal vias 164 enable heat to be transferred from the heat dissipation layer 170 above the package substrate 160 to the bottom of the package substrate 160 (i.e., serve as heat dissipation paths), which is described in more detail with reference to FIG. 1G.

FIG. 1F-1 is a top view of the chip package structure shown in FIG. 1F, in accordance with some embodiments. In FIG. 1F-1, a single thermal via 164 is formed in the package substrate 160, and the thermal via 164 has a rectangular frame shape surrounding the CoW device 150 in plan view (e.g., top view). In some embodiments, the ratio (i.e., W1/W2) of the lateral dimension W1 (e.g., width) of the thermal via 164 to the lateral dimension W2 (e.g., width) of the package substrate 160 is within a range of 0.05 percent to 10 percent, although other ratio ranges may be used.

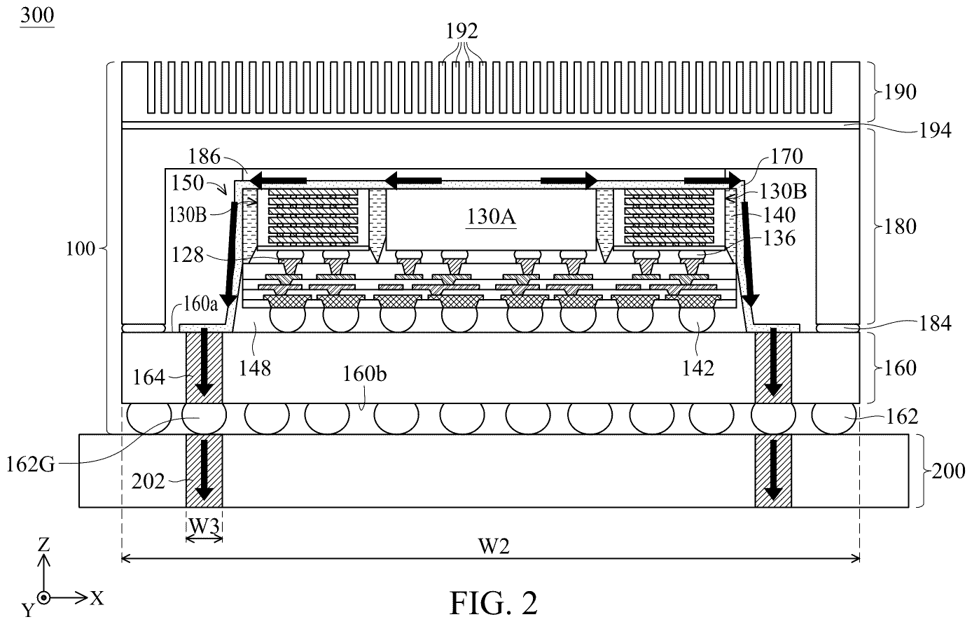

FIGS. 1F-2, 1F-3, and 1F-4 are top views showing different arrangements of thermal vias 164 in the package substrate 160, in accordance with some alternative embodiments. For simplicity, the CoW device 150 is not shown in these figures. In FIG. 1F-2, 1F-3, and 1F-4, multiple thermal vias 164 are formed in the package substrate 160 and are arranged in a substantially rectangular frame shape when viewed from the top, wherein each thermal via 164 has a rectangular (or square), circular, or oval cross-sectional shape. Other suitable arrangements and/or cross-sectional shapes may be used.

As shown in FIG. 1G, a heat dissipation layer 170 is conformally formed over (e.g., in contact with) the top surface of the CoW device 150 (e.g., the top surfaces of the package components 130A and 130B and the encapsulant 140), the sidewalls of the CoW device 150 (e.g., the sidewalls of the encapsulant 140), the sidewalls (i.e., outer surface) of the underfill layer 148 (e.g., fillet portion 149), and the top surface 160a of the package substrate 160, in accordance with some embodiments. The heat dissipation layer 170 is formed to continuously extend from the top surface of the CoW device 150 along the sidewalls of the CoW device 150 (and the sidewalls of the underfill layer 148) to the top surface 160a of the package substrate 160, in accordance with some embodiments. For example, the heat dissipation layer 170 includes a first portion 171 covering (i.e., overlapping) the top surface of the CoW device 150, a second portion 172 covering the sidewalls of the CoW device 150 and the outer surface of the underfill layer 148 (e.g., fillet portion 149), and a third portion 173 covering the top surface 160a of the package substrate 160 and in contact (e.g., thermal contact) with one or more thermal vias 164 in the package substrate 160, wherein these portions 171, 172 and 173 are connected to each other, as shown in FIG. 1H,. Accordingly, the heat dissipation layer 170 is configured to transfer (e.g., dissipate) heat generated from the package components 130A and 130B (e.g., IC dies) of the CoW device 150 to the underlying package substrate 160, which may then transfer (e.g., dissipate) the heat to the bottom of the package substrate 160 via the thermal vias 164, as indicated by the horizontal and downward arrows in FIG. 1G. In other words, a thermal conductive path is formed from the package components 130A and 130B to the bottom of the package substrate 160.

In some embodiments, the heat dissipation layer 170 may include a thermal interface material (TIM), graphite, graphene, diamond-like carbon (DLC), solder paste, nano silver paste, or another heat dissipation material with high thermal conductivity. The thermal interface material may include a thermal grease (or thermal paste), a thermal gel, a thermal pad, a phase-change material (PCM), a phase-change metal alloy, or a thermal conductive adhesive. The composition of the thermal grease may include silicon oil base, zinc oxide (ZnO), or silver (Ag), but it is not limited thereto. The composition of the thermal gel may include aluminum (Al), silver (Ag), silicon oil, olefin, or paraffin wax, but it is not limited thereto. The composition of the thermal pad may include silicone rubber, glass fiber, polyester based material, or silicone oil filled material, but it is not limited thereto. The composition of the phase-change material may include polyolefin resin, acrylic, aluminum (Al), aluminum oxide, or carbon nanofiber tube, but it is not limited thereto. The composition of the phase-change metal alloy may include indium (In), alloy of indium (In) and silver (Ag), alloy of tin (Sn), silver (Ag) and copper (Cu), alloy of indium (In), tin (Sn) and bismuth (Bi), but it is not limited thereto. The composition of the thermal conductive adhesive may include epoxy, iron (Fe), silver (Ag), or nickel (Ni), but it is not limited thereto. In some embodiments, the material of heat dissipation layer 170 is selected such that its thermal resistance is less than about 5 K/W. In some embodiments, the heat dissipation layer 170 may include a material with a higher thermal conductivity (e.g., about 10 W/m·K to about 50 W/m·K or more) than the materials used for the package components 130 (e.g., silicon) and the encapsulant 140 (e.g., molding compound).

In some embodiments, the heat dissipation layer 170 may be formed by coating, spraying, plating, printing, molding, placing, or another suitable deposition or growth process. In some embodiments, the formation of heat dissipation layer 170 may require curing. In some alternative embodiments, the formation of heat dissipation layer 170 may not require curing.

In some embodiments, the heat dissipation layer 170 is formed to completely cover the entire CoW device 150, as shown in FIG. 1G (see also FIG. 1G-1, which is described below). Furthermore, the heat dissipation layer 170 is electrically connected (e.g., through the thermal vias 164) to one or more conductive connectors 162G that may serve as ground contacts (i.e., are electrically grounded). Accordingly, the heat dissipation layer 170 can also serve as an electromagnetic interference shielding layer to prevent external signals from interfering with the CoW device 150 (e.g., by reducing the coupling with radio waves, electromagnetic fields, electrostatic fields, etc.). In this way, the performance reliability of the package structure may be improved.

In cases where the heat dissipation layer 170 serves as an electromagnetic interference shielding layer, the heat dissipation layer 170 may be made of an electrically conductive material. Materials used for the electromagnetic interference shielding layer may include copper, nickel, an alloy of nickel and iron, an alloy of copper and nickel, silver, etc., but they are not limited thereto.

In some embodiments, the entire heat dissipation layer 170 may have a uniform thickness T1 (e.g., in the Z-direction), although the disclosure is not limited thereto. In some embodiments, the ratio (i.e., T1/T2) of the thickness T1 of the heat dissipation layer 170 to the thickness T2 of the CoW device 150 (which may be measured from the top surface 160a of the package substrate 160 to the top surface of the CoW device 150) is within a range of 0.05 percent to 50 percent, although other ratio ranges may be used. In some embodiments, an included angle θ1 between the second portion 172 of the heat dissipation layer 170 (i.e., the portion covering the sidewalls of the CoW device 150 and the outer surface of the underfill layer 148 (e.g., fillet portion 149)) and the top surface 160a of the package substrate 160 is within a range of 5 degrees to 90 degrees.

FIG. 1G-1 is a top view of the chip package structure shown in FIG. 1G, in accordance with some embodiments, in which the heat dissipation layer 170 is shown as a single continuous and complete structure that completely covers the top surface of the CoW device 150, the sidewalls of the CoW device 150, the sidewalls (outer surface) of the underfill layer 148 (e.g., fillet portion 149), and the thermal via(s) 164 exposed at the top surface 160a of the package substrate 160. As mentioned above, this configuration of the heat dissipation layer 170 can provide both heat dissipation and electromagnetic interference shielding functions.

The heat dissipation layer 170 may also have various arrangement variations. For example, FIGS. 1G-2, 1G-3, and 1G-4 are top views showing different arrangements of the heat dissipation layer 170, in accordance with some alternative embodiments. In FIG. 1G-2, the heat dissipation layer 170 includes multiple discrete portions 170A, 170B, 170C and 170D, each extending across over the top surfaces of different types of package components (e.g., package components 130A and 130B) in a horizontal direction (e.g., the X-direction). In FIG. 1G-3, the heat dissipation layer 170 includes multiple discrete portions 170A, 170B, 170C and 170D, each extending across over the top surfaces of the same type of package components (e.g., package components 130A or 130B) in a horizontal direction (e.g., the Y-direction). In FIG. 1G-4, the heat dissipation layer 170 includes multiple discrete portions 170A, 170B, 170C, 170D, 170E, 170F, 170G, 170H, 170I and 170J, each extending across over the top surface of a single package component (e.g., package component 130A or 130B) in a horizontal direction (e.g., the X-direction or Y-direction). In these figures, each portion of the heat dissipation layer 170 also extends along the corresponding sidewall of the CoW device 150 to the top surface 160a of the package substrate 160 to contact the exposed thermal via(s) 164 to form a thermal conductive path from the package components 130A and 130B to the bottom of the package substrate 160. It should be understood that the structures, numbers or arrangements described above with reference to FIGS. 1G-1 to 1G-4 are only illustrative, and are not intended to be, and should not be construed to be, limiting to the present disclosure.

As shown in FIG. 1H, a lid 180 is attached to the package substrate 160 and the CoW device 150 to form a chip package structure 100 (e.g., CoWoS package 100), in accordance with some embodiments. The lid 180 may be attached to protect the CoW device 150 and the package substrate 160 and to spread heat generated from the CoW device 150 (e.g., from the package components 130A and 130B) to a larger area, thereby dissipating the heat from the CoW device 150 (as indicated by the upward arrows in FIG. 1H). Furthermore, attaching the lid 180 also helps reduce warpage of the entire package structure. The lid 180 may be formed from a material having a high thermal conductivity, such as steel, stainless steel, copper, aluminum, combinations thereof, or the like. In some embodiments, the lid 180 may be formed of a material having a thermal conductivity from about 100 W/m·K to about 800 W/m·K, such as about 800 W/m·K. In some embodiments, the lid 180 is a single continuous material. In other embodiments, the lid 180 may include multiple pieces that may be the same or different materials.

As shown in FIG. 1H, the lid 180 covers and surrounds the CoW device 150. For example, the lid 180 includes a plate portion 181 and a frame portion 182. The plate portion 181 extends substantially parallel to the package substrate 160. The plate portion 181 covers the CoW device 150 and is connected to the heat dissipation layer 170 via thermal interface material (TIM) 186. The frame portion 182 is located at edges of the plate portion 181 and protrudes towards the package substrate 160 in a direction substantially perpendicular to the package substrate 160. The frame portion 182 is connected to the package substrate 160 through adhesive 184. Accordingly, the CoW device 150 may be enclosed by the package substrate 160, the frame portion 182 and the plate portion 181. The adhesive 184 may have a greater adhering ability, but a lower thermal conductivity than the TIM 186. Details of the adhesive 184 and the TIM 186 are not described here.

In some embodiments, the material of the TIM 186 is different from the material of the underlying heat dissipation layer 170. For example, the TIM 186 may include a material with better thermal conductivity in the thickness direction (or vertical direction) than the material used for the heat dissipation layer 170, whereas the heat dissipation layer 170 may include a material with better thermal conductivity in the transverse direction (or span direction) than the material used for the TIM 186.

In some alternative embodiments, the TIM 186 may be omitted, and the plate portion 181 is directly connected to the heat dissipation layer 170. In such embodiments, the heat dissipation layer 170 may serves as a thermal interface material (TIM) to dissipate heat generated from the CoW device 150 (e.g., from the package components 130A and 130B) to the overlying lid 180.

In some embodiments, an optional heat sink 190 (depicted by dashed lines) is also provided on the top surface of the lid 180 to improve heat dissipation efficiency, as shown in FIG. 1H. The heat sink 190 may include fins 192 or other features that may be configured to increase the surface area of the heat sink 190 that comes into contact with a cooling medium, such as ambient air. In some embodiments, the heat sink 192 may be a separate component from the lid 180 (e.g., it may be attached to the lid 180 through another TIM 194) or it may be integrally formed with the lid 180. In other embodiments, the heat sink 192 may be omitted.

It should be understood that High Performance Computing (HPC) has become increasingly popular and widely used in advanced networking and server applications, especially for artificial intelligence (AI) related products that require high data rates, increased bandwidth and reduced latency. There will also be higher cooling requirements since these HPC applications require extremely high power, as well as high power density, at die regions.

As noted above, by forming the heat dissipation layer 170 and corresponding thermal via(s) 164 in the package substrate 160 (which may be collectively referred to as heat dissipation enhanced structures) to serve as one or more additional heat transfer paths, the heat generated by the IC dies (i.e., the package components 130A and 1030B) within the CoW device 150 can be transferred laterally and downwardly to the bottom of the package substrate 160 along these heat transfer paths (rather than just being dissipated upward through upper heat dissipation mechanisms, such as a thermal lid 180 and/or a heat sink 190 above the CoW device 150). Therefore, heat accumulation between the CoW device 150 and the upper heat dissipation mechanisms can be reduced or avoided, thereby improving the heat dissipation efficiency of the entire package structure.

Additionally or alternatively, the heat dissipation layer 170 can also serve as an electromagnetic interference shielding layer to prevent the CoW device 150 from being interfered by external signals (as mentioned above), in accordance with some embodiments. As a result, the performance reliability of the package structure 100 may be improved.

FIG. 2 is a cross-sectional view of an integrated circuit device 300, in accordance with some embodiments. The integrated circuit device 300 is formed by bonding the chip package structure 100 described above to a system board 200 (sometimes also referred to as a mother board). In some embodiments, after the chip package structure 100 is formed, it is attached to a system board 200 using the conductive connectors 162. For example, the conductive connectors 162 (e.g., solder balls) are reflowed after the placement of the chip package structure 100 onto the system board 200, to physically and electrically connect the chip package structure 100 to the system board 200. Other suitable bonding schemes may be used.

In some embodiments, the system board 200 is a printed circuit board (PCB), which may be used to interconnect various electronic components thereon in order to provide the desired functionality for the user. Conductive features (e.g., conductive lines, vias, contact pads, etc.), electronic components (e.g., active or passive components), and/or Input/Output (I/O) interface connectors (e.g., slots) on and/or within the system board 200 are not shown for the sake of simplicity. In some embodiments, the system board 200 may be coupled both electrically and physically to another substrate on a side of the system board 200 opposite the chip package structure 100. Another substrate may provide a structural base and an electrical interface from the system board 200 and/or the chip package structure 100 to other devices and systems. In some embodiments, the system board 200 may be bonded to another substrate using external connections (not shown), which may be solder balls or other suitable conductive connections.

Still referring to FIG. 1F, one or more thermal vias 202 are also pre-formed in (e.g., penetrating through) the package substrate 200 and may be configured to dissipate the heat from the chip package structure 100 to the bottom of the package substrate 200 (as indicated by the downward arrows in FIG. 1F), in accordance with some embodiments. The location of the thermal vias 202 may correspond to (e.g., vertically overlap) the location of one or more conductive connectors 162 that are coupled to the thermal vias 164 within the package substrate 160, in accordance with some embodiments. Although not shown, the thermal via(s) 202 may have a similar arrangement and shape in plan view as the thermal via(s) 164 shown in FIGS. 1F-1 to 1F-4. In some embodiments, the ratio (i.e., W3/W2) of the lateral dimension W3 (e.g., width) of the thermal via 202 to the lateral dimension W2 (e.g., width) of the package substrate 160 is within a range of 0.05 percent to 10 percent, although other ratio ranges may be used. Through the above configurations, the heat dissipation efficiency of the integrated circuit device 300 is also improved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

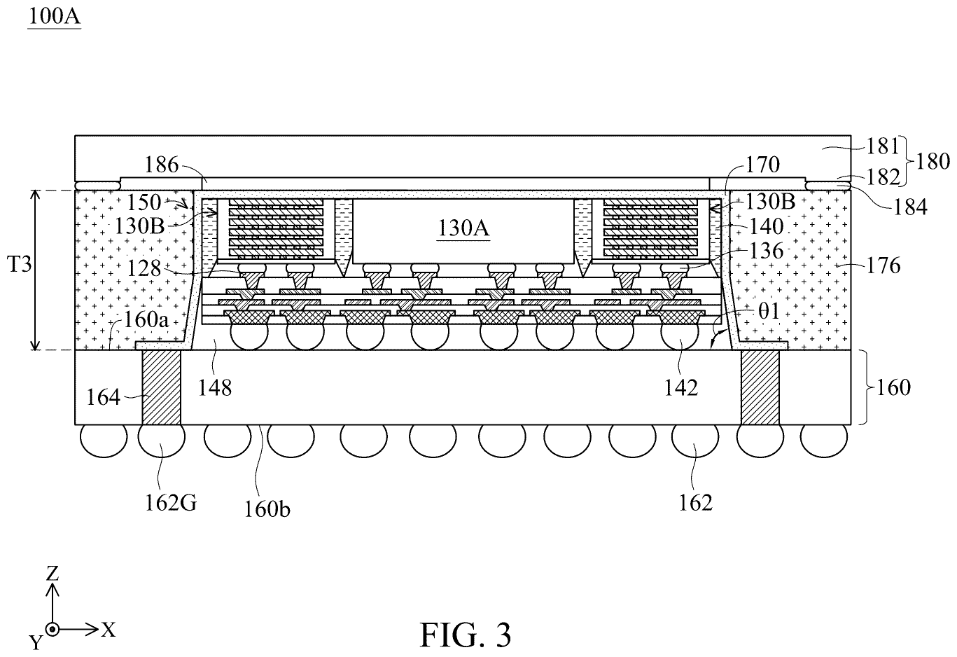

Many variations and/or modifications can be made to embodiments of the disclosure. For example, the aforementioned chip package structure (e.g., CoWoS package) can have some variations. Some variations of some embodiments are described below with reference to FIGS. 3 to 8.

FIG. 3 is a cross-sectional view of a chip package structure 100A, in accordance with some alternative embodiments. Chip package structure 100A is similar to chip package structure 100 previously described in FIG. 1H, except that the chip package structure 100A further includes a molding layer 176 disposed over the top surface 160a of the package substrate 160. Forming the molding layer 176 helps to relieve and counterbalance potential stresses in the package structure.

The molding layer 176 covers (e.g., contacts) portions of the heat dissipation layer 170 (e.g., the second portion 172 and third 173, as shown in FIG. 1G) over the sidewalls of the CoW device 150 and the outer surface of the underfill layer 148 and over the top surface 160a of the package substrate 160, but exposes the top surface of a portion of the heat dissipation layer 170 (e.g., the first portion 171, as shown in FIG. 1G) over the top surface of the CoW device 150, in accordance with some embodiments. This facilitates the heat dissipation of the chip package structure 100A. In various embodiments, the thickness T3 (in the Z-direction) of the molding layer 176 may be equal to or different from (larger or smaller than) the thickness T2 of the CoW device 150 (see FIG. 1G). The molding layer 176 extends horizontally to edges of the package substrate 160 so that the sidewalls of the molding layer 176 are vertically aligned with corresponding sidewalls of the package substrate 160, in accordance with some embodiments.

In some embodiments, the material of the molding layer 176 includes a resin such as an epoxy resin, a phenolic resin or a thermosetting resin material. In some embodiment, the molding layer 300 is made of a molding material (e.g., molding compound) with an appropriate thermal expansion coefficient (CTE) to reduce CTE mismatch with the package substrate 160. In some embodiments, the molding layer 176 is formed by a molding process such as injection molding, transfer molding, compression molding, or the like, for example, after the heat dissipation layer 170 is formed (e.g., in the processing step illustrated in FIG. 1G).

Still referring to FIG. 3, in the chip package structure 100A, the lid 180 is attached to the top surface of the molding layer 176 rather than to the package substrate 160. The structure, material, and installation method of the lid 180 may be similar to those previously described in FIG. 1H. The lid 180 can help to dissipate heat from the CoW device 150 and alleviate the warpage of the entire package structure.

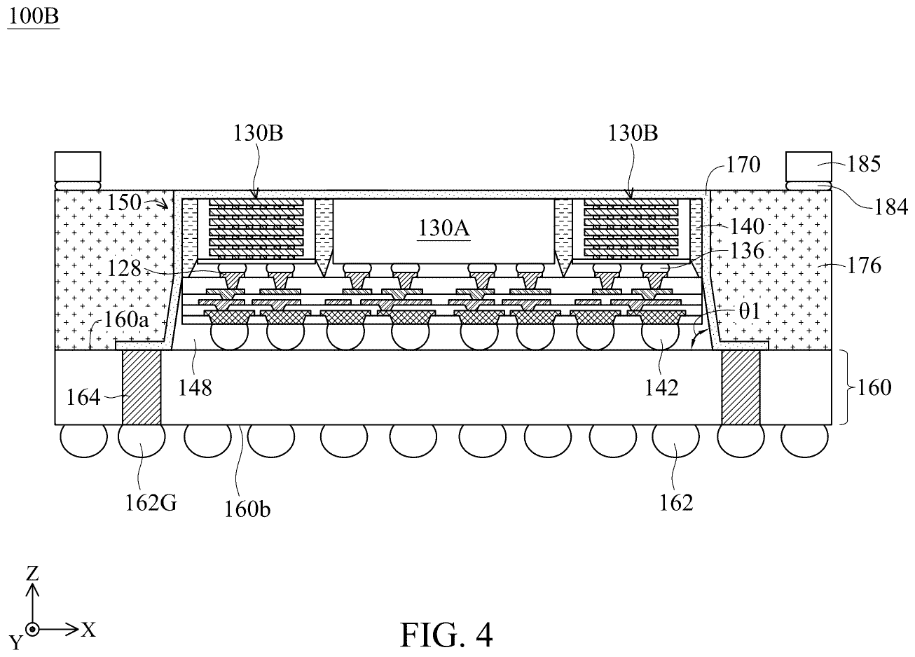

FIG. 4 is a cross-sectional view of a chip package structure 100B, in accordance with some alternative embodiments. Chip package structure 100B is similar to chip package structure 100A previously described in FIG. 3, except that the lid 180 is replaced by a stiffener ring 185. Although not shown, the stiffener ring 185 may be arranged along the edges of the package substrate 160 in plan view. The stiffener ring 185 may be attached to the top surface of the molding layer 176 through adhesive 184. The stiffener ring 185 can help to alleviate the warpage of the entire package structure.

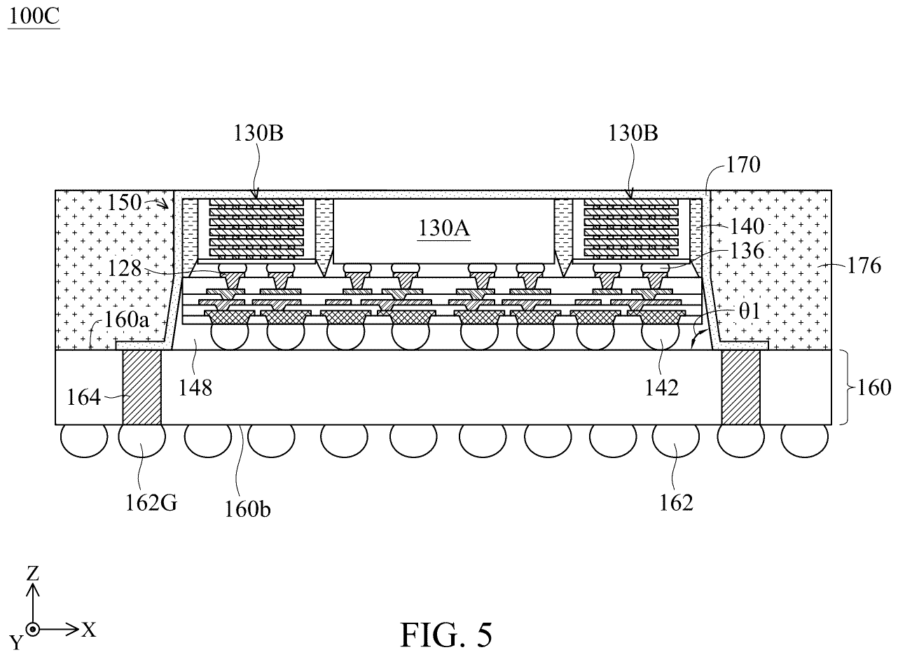

FIG. 5 is a cross-sectional view of a chip package structure 100C, in accordance with some alternative embodiments. Chip package structure 100C is similar to chip package structure 100A previously described in FIG. 3, except that the lid 180 is omitted. In such embodiments, stress control components such as lids and stiffener rings may be omitted since warping may be less of a problem.

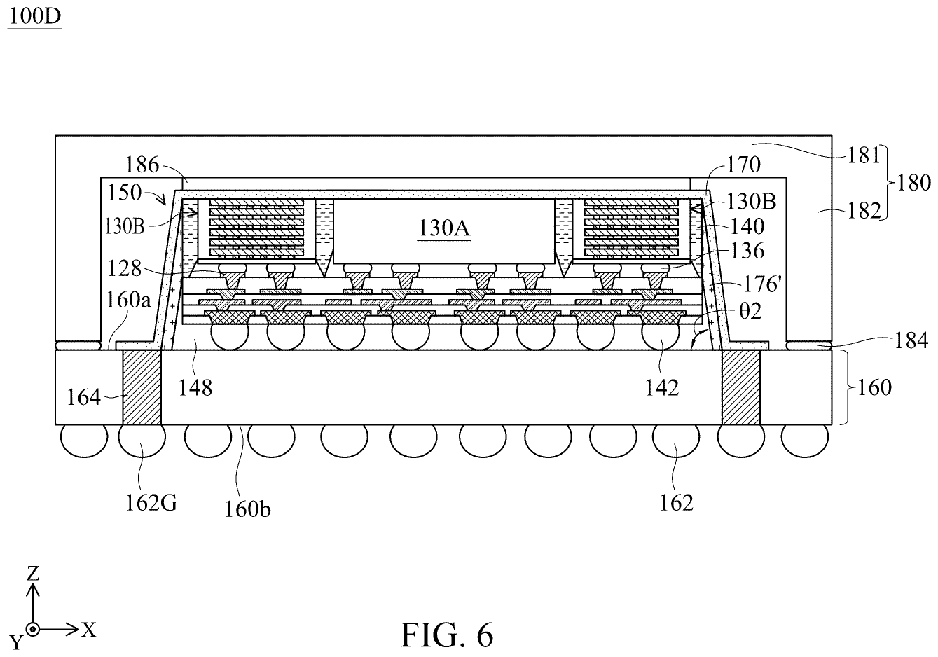

FIG. 6 is a cross-sectional view of a chip package structure 100D, in accordance with some alternative embodiments. Chip package structure 100D is similar to chip package structure 100 previously described in FIG. 1H, except that the chip package structure 100D further includes a molding layer 176′ disposed around (e.g., in direct contact with) the CoW device 150 (and the underfill layer 148) over the top surface 160a of the package substrate 160. Similarly, forming the molding layer 176′ helps to relieve and counterbalance potential stresses in the package structure.

The molding layer 176′ may be formed after the CoW device 150 is bonded to the package substrate 160 and before the heat dissipation layer 170 is formed (e.g., in the processing step illustrated in FIG. 1F). The molding layer 176′ is formed to cover the sidewalls of the CoW device 150 (e.g., the sidewalls of the encapsulant 140), the sidewalls (i.e., outer surface) of the underfill layer 148 (e.g., fillet portion 149), and a portion of the top surface 160a of the package substrate 160 (but exposes the thermal vias 164), in accordance with some embodiments. In this manner, after the heat dissipation layer 170 is formed, the heat dissipation layer 170 may include a first portion covering the top surface of the CoW device 150, a second portion covering the outer surface of the molding layer 176′, and a third portion 173 covering the top surface 160a of the package substrate 160 and in contact (e.g., thermal contact) with one or more thermal vias 164 in the package substrate 160. In some embodiments, an included angle θ2 between the second portion of the heat dissipation layer 170 covering the outer surface of the molding layer 176′ and the top surface 160 a of the package substrate 160 is within a range of 5 degrees to 90 degrees. Through the above configuration, the heat generated from the CoW device 150 can also be transferred to the package substrate 160 through the heat dissipation layer 170, similar to the embodiments described above.

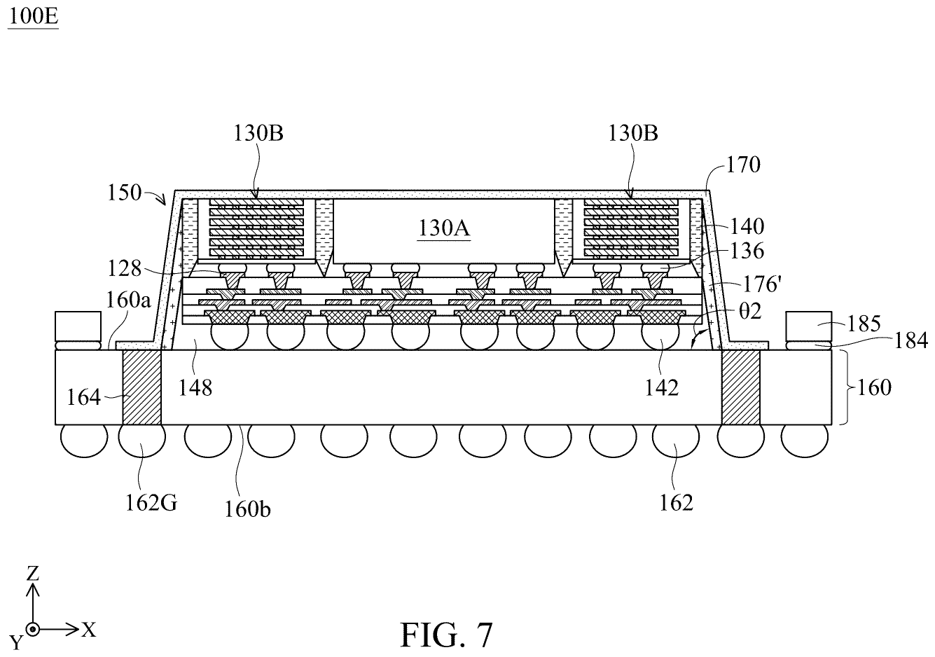

FIG. 7 is a cross-sectional view of a chip package structure 100E, in accordance with some alternative embodiments. Chip package structure 100E is similar to chip package structure 100D previously described in FIG. 6, except that the lid 180 is replaced by a stiffener ring 185. Although not shown, the stiffener ring 185 may be arranged along the edges of the package substrate 160 and may be arranged around the CoW device 150 (and the molding layer 176′) in plan view. The stiffener ring 185 may be attached to the top surface 160 a of the package substrate 160 through adhesive 184. The stiffener ring 185 can help to alleviate the warpage of the entire package structure.

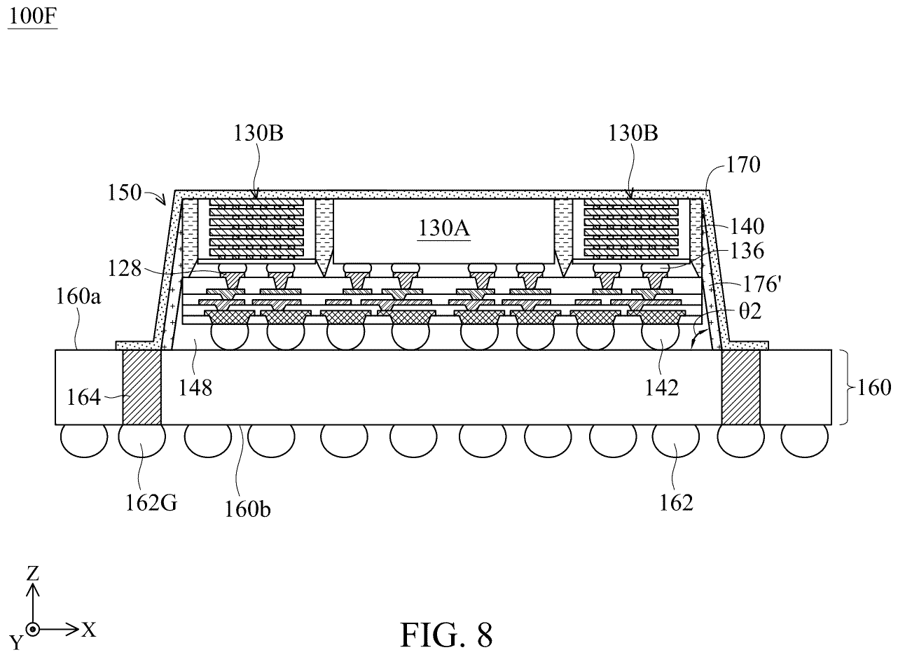

FIG. 8 is a cross-sectional view of a chip package structure 100F, in accordance with some alternative embodiments. Chip package structure 100F is similar to chip package structure 100D previously described in FIG. 6, except that the lid 180 is omitted. In such embodiments, stress control components such as lids and stiffener rings may be omitted since warping may be less of a problem.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily.

In addition, while the present disclosure is described using embodiments in which the heat dissipation layer 170 is a single layer, embodiments are expressly contemplated herein in which the heat dissipation layer 170 is a composite layer including a plurality of sub-layers formed of different materials. For example, the heat dissipation layer may include a combination of an adhesive material sub-layer and a thermal conductive material sub-layer. In some embodiments, the adhesive material sub-layer has better stickiness than the thermal conductive material sub-layer, whereas the thermal conductive material sub-layer has better electrical conductivity than the adhesive material sub-layer. In some embodiments, the adhesive material sub-layer is adjacent to or in contact with the CoW, the underfill layer, the molding layer and/or the package substrate, and the thermal conductive material sub-layer is located above the adhesive material sub-layer.

In summary, the embodiments of the present disclosure have some advantageous features. By forming (e.g., covering) a heat dissipation layer over the top surface and sidewalls of the CoW device and extending to the top surface of the package substrate, and forming one or more thermal vias in the package substrate and thermally contacting the heat dissipation layer, it provides additional lateral and downward heat transfer path(s) from the IC dies of the CoW device to the bottom of the package substrate for better heat dissipation. Therefore, heat accumulation between the CoW device and the upper heat dissipation mechanisms (e.g., thermal lid and/or heat sink) can be reduced or avoided, thereby improving heat dissipation efficiency of the entire package structure. In cases where the thermal vias are electrically grounded, the heat dissipation layer can also serve as an electromagnetic interference shielding layer to prevent the CoW device from being interfered by external signals. As a result, the performance reliability of the package structure is improved.

In accordance with some embodiments, a chip package structure is provided. The chip package structure includes a package substrate, a semiconductor device, a heat dissipation layer, and at least one thermal via. The semiconductor device is mounted on the package substrate. The heat dissipation layer includes a first portion covering the top surface of the semiconductor device, a second portion covering the sidewall of the semiconductor device, and a third portion covering the top surface of the package substrate. The first portion, second portion and third portion are connected to each other. The at least one thermal via is formed through the package substrate to contact the third portion of the heat dissipation layer.

In accordance with some embodiments, a chip package structure is provided. The chip package structure includes a package substrate, an interposer, at least one first package component and at least one first package component, an encapsulant, a heat dissipation layer, and at least one thermal via. The interposer is mounted on the package substrate. The first and second package components are mounted on the interposer. The encapsulant is located on the interposer and surrounds the first and second package components. The heat dissipation layer continuously extends from the top surfaces of the first and second package components and the encapsulant along the sidewalls of the encapsulant to the top surface of the package substrate. The at least one thermal via is formed through the package substrate to contact the heat dissipation layer.

In accordance with some embodiments, a method of forming a chip package structure is provided. The method includes mounting a semiconductor device on a package substrate. The method also includes forming a heat dissipation layer over the semiconductor device and the package substrate, wherein the heat dissipation layer continuously extends from the top surface of the semiconductor device along the sidewall of the semiconductor device to the top surface of the package substrate. In addition, the method includes forming at least one thermal via through the package substrate to contact the heat dissipation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package structure, comprising:
a package substrate;
a semiconductor device mounted on the package substrate;
a heat dissipation layer comprising:
a first portion covering a top surface of the semiconductor device;
a second portion covering a sidewall of the semiconductor device; and
a third portion covering a top surface of the package substrate, wherein the first portion, the second portion, and the third portion are connected to each other; and
at least one thermal via formed through the package substrate to contact the third portion of the heat dissipation layer.

2. The chip package structure as claimed in claim 1, wherein the semiconductor device comprises:
an interposer;
a plurality of semiconductor dies mounted on the interposer; and
an encapsulant located over the interposer and surrounding the semiconductor dies,
wherein the first portion of the heat dissipation layer covers top surfaces of the semiconductor dies and the encapsulant, and the second portion of the heat dissipation layer covers a sidewall of the encapsulant, and
wherein the heat dissipation layer include a material with a higher thermal conductivity than materials used for the semiconductor dies and the encapsulant.

3. The chip package structure as claimed in claim 1, further comprising:
an underfill layer formed in a gap between a bottom surface of the semiconductor device and the top surface of the package substrate, the underfill layer comprising a fillet portion that extends to the sidewall of the semiconductor device, wherein the second portion of the heat dissipation layer covers the fillet portion.

4. The chip package structure as claimed in claim 1, wherein the at least one thermal via is arranged around the semiconductor device and overlaps the third portion of the heat dissipation layer in a plan view.

5. The chip package structure as claimed in claim 1, further comprising:
a lid located over the package substrate and the semiconductor device, the lid comprising:
a plate portion covering the semiconductor device and connected to the first portion of the heat dissipation layer through a thermal interface material; and
a frame portion extending from edges of the plate portion toward the package substrate and connected to the package substrate through an adhesive,
wherein the heat dissipation layer includes a different material than the thermal interface material.

6. The chip package structure as claimed in claim 1, further comprising:
a molding layer formed over the top surface of the package substrate, wherein the molding layer covers the second portion and the third portion of the heat dissipation layer, but exposes the first portion of the heat dissipation layer.

7. The chip package structure as claimed in claim 6, further comprising:
a lid located over the package substrate, the semiconductor device and the molding layer, wherein the lid is connected to the first portion of the heat dissipation layer through a thermal interface material, and is connected to a top surface of the molding layer through an adhesive.

8. The chip package structure as claimed in claim 6, further comprising:
a ring located over the package substrate and the molding layer, wherein the ring is connected to a top surface of the molding layer through an adhesive, and is arranged along edges of the package substrate.

9. The chip package structure as claimed in claim 1, further comprising:
a molding layer formed over the top surface of the package substrate and in contact with the sidewall of the semiconductor device, wherein the second portion of the heat dissipation layer covers the molding layer.

10. The chip package structure as claimed in claim 9, further comprising:
a lid located over the package substrate, the semiconductor device and the molding layer, wherein the lid is connected to the first portion of the heat dissipation layer through a thermal interface material, and is connected to the top surface of the package substrate through an adhesive.

11. The chip package structure as claimed in claim 9, further comprising:
a ring located over the package substrate, wherein the ring is connected to the top surface of the package substrate through an adhesive, and is arranged around the semiconductor device and the molding layer.

12. The chip package structure as claimed in claim 1, further comprising:
a plurality of conductive connectors located on a bottom surface of the package substrate, wherein the at least one thermal via is connected to at least one of the conductive connectors that is electrically grounded.

13. A chip package structure, comprising:
a package substrate;
an interposer mounted on the package substrate;
at least one first package component and at least one second package component mounted on the interposer;
an encapsulant located on the interposer and surrounding the at least one first package component and the at least one second package component;
a heat dissipation layer continuously extending from top surfaces of the at least one first package component, the at least one second package component and the encapsulant along sidewalls of the encapsulant to a top surface of the package substrate; and
at least one thermal via formed through the package substrate to contact the heat dissipation layer.

14. The chip package structure as claimed in claim 13, wherein the heat dissipation layer is single continuous structure that completely covers the top surfaces of the at least one first package component, the at least one second package component and the encapsulant, the sidewalls of the encapsulant, and the at least one thermal via exposed at the top surface of the package substrate.

15. The chip package structure as claimed in claim 13, wherein the heat dissipation layer comprises a plurality of discrete portions, each extending in a first horizontal direction across at least one top surface of the at least one first package component and at least one top surface of the at least one second package component.

16. The chip package structure as claimed in claim 13, wherein the heat dissipation layer comprises a plurality of discrete portions, each extending in a first horizontal direction across at least one top surface of the at least one first package component or at least one top surface of the at least one second package component.

17. The chip package structure as claimed in claim 13, wherein the heat dissipation layer comprises a plurality of discrete portions, each extending in a first horizontal direction across at least one top surface of the at least one first package component or in a second horizontal direction across at least one top surface of the at least one second package component, wherein the second horizontal direction is different from the first horizontal direction.

18. The chip package structure as claimed in claim 13, further comprising a lid located over the at least one first package component and the at least one second package component and connected to the heat dissipation layer through a thermal interface material.

19. A method of forming a chip package structure, comprising:
mounting a semiconductor device on a package substrate;
forming a heat dissipation layer over the semiconductor device and the package substrate, wherein the heat dissipation layer continuously extends from a top surface of the semiconductor device along a sidewall of the semiconductor device to a top surface of the package substrate; and
forming at least one thermal via through the package substrate to contact the heat dissipation layer.

20. The method as claimed in claim 19, further comprising:
forming a plurality of conductive connectors on a bottom surface of the package substrate, wherein the at least one thermal via is connected to at least one of the conductive connectors that is electrically grounded.
